(19) United States
(12) Patent Application Publication
(10) Pub. No.: US 2023/0103714 A1
(43) Pub. Date: Apr. 6, 2023

(54) PLASMA PROCESSING APPARATUS AND OPERATING METHOD OF PLASMA PROCESSING APPARATUS

(71) Applicant: Hitachi High-Tech Corporation, Minato-ku, Tokyo (JP)

(72) Inventors: Takuya Yasunaga, Tokyo (JP); Hiroshi Sasaki, Tokyo (JP); Masahiro Nagatani, Tokyo (JP)

(21) Appl. No.: 16/977,596

(22) PCT Filed: Dec. 17, 2019
(86) PCT No.: PCT/JP2019/049304

§ 371 Date: Sep. 2, 2020

(51) Int. Cl. H01J 37/32

(52) U.S. Cl. CPC H01J 37/32146; H01J 37/32577; H01J 37/32128; H01J 2237/24564; H01J 2237/334

(57) ABSTRACT

To accurately detect a waveform of a high frequency power supplied to a sample stage or electrodes inside the sample stage and improve a yield and an operation efficiency, a plasma processing apparatus that processes a wafer to be processed placed on an upper surface of the sample stage disposed in a processing chamber disposed inside a vacuum container by using plasma formed in the processing chamber, includes: a high frequency power supply that forms the high frequency power supplied in a pulsed shape to the plasma or the wafer at a predetermined period during processing of the wafer; a determining device that a waveform of a voltage or a current from a value of the voltage or the current of the high frequency power detected at an interval longer than the period and determines whether the waveform is within a predetermined allowable range; and a notification device that notifies a user of a determination result of the determining device and a shape of the waveform.

### TECHNICAL FIELD

The present invention relates to a plasma processing apparatus and an operating method of a plasma processing apparatus that processes a wafer disposed in a processing chamber by using plasma formed in the processing chamber inside a vacuum container, and relates to a plasma processing apparatus and a plasma processing method that processes the wafer while supplying high frequency power by repeating large and small amplitudes at a predetermined time interval to electrodes inside a sample stage on which the wafer is placed.

### BACKGROUND ART

As an example of a technique that detects a value of a high frequency power through a sample stage in a processing chamber or electrodes inside the processing chamber to determine whether there is an abnormality in a state of processing using plasma in the processing chamber in a plasma processing apparatus for a semiconductor wafer, a technique described in JP-A-2017-162713 (PTL 1) is known. PTL 1 includes a high frequency power supply connected to the electrodes that form the sample stage every predetermined period, a discharge sensor that detects a discharge state of the plasma formed in the processing chamber by the high frequency power supplied from the electrodes as a potential through the sample stage or the electrodes inside the sample stage, and a signal analysis unit that analyzes a signal from the discharge sensor and detects the abnormality.

In particular, PTL 1 discloses that the signal analysis unit compares an Nth average value, which is an average value of absolute values of signals from the discharge sensor that detects the potential of the high frequency power through the electrodes in a Nth period of a sampling period during processing, with a (N-n)th average value of absolute values of signals in a nearest (N-n)th sampling period before the Nth period to calculate an increase and decrease rate, and when the increase and decrease rate exceeds a predetermined rate, it is determined that the abnormality occurs.

Furthermore, JP-A-2016-051542 (PTL 2) discloses a high frequency power supply that outputs a high frequency power in a pulse-shaped waveform, that includes a RF power control unit that adjusts the output of the high frequency power, and a DC-RF conversion unit that amplifies and outputs a pulse output signal from the RF power control unit, and that includes a configuration in which a pulse waveform control unit disposed in the RF power control unit controls a pulse output. In particular, PTL 2 discloses a technique that performs processing of increasing each rising and falling time at a predetermined time pitch when a difference between an output power and a target output power is equal to or greater than a reference value in the pulse waveform control unit, and stops the processing when the difference becomes equal to or less than the reference value.

### CITATION LIST

### Patent Literature

PTL 1: JP-A-2017-162713
PTL 2: JP-A-2016-051542

### SUMMARY OF INVENTION

### Technical Problem

The related-art technique described above has a problem since the following points are not sufficiently taken into consideration.

That is, in the related-art technique, a signal output from a power supply is detected, and the signal is compared with the reference value to determine whether the value is correct, or it is determined whether a reduction rate of the signal obtained by sampling a power from the high frequency power supply applied to the sample stage in the processing chamber or the electrodes inside the sample chamber a plurality of times at a predetermined time interval in each of a plurality of specific periods is normal. However, in such a related-art technique, it is unclear whether a waveform of the high frequency power when output from the power supply is in accordance with a predetermined reference or target shape, and no consideration is given to a point of detecting and determining the waveform.

Therefore, in the related-art technique, even when a desired adjustment of the waveform of the high frequency power is realized, it is unclear whether a resulting waveform is close to a desired one. Thus, there is a problem that a shape adjustment after processing such as etching of a processing target film on an upper surface of a wafer which is a processing target sample performed while supplying the high frequency power cannot be realized with high accuracy and a processing yield is impaired.

As a solution for solving the above problem, it is conceivable to confirm the power output from the high frequency power supply at every predetermined period. For example, in PTL 2, when a maintenance work for confirming whether a pulse control device normally operates is regularly performed, a time during which the power supply is stopped is increased and an efficiency is decreased. Furthermore, in PTL 1, when it is attempted to detect the output from the high frequency power supply during a processing of the wafer at a predetermined sampling interval and confirm that there is a waveform within an allowable range from the reference or target shape, when the power is supplied from the high frequency power supply by repeating large and small amplitudes at a predetermined time interval, in order to accurately detect a waveform that increases or decreases at each time interval from a signal detected at a sampling interval that is correspondingly shorter than the interval and determine whether there is an abnormality in a short time, a required function of a sensor or a determining device is increased and a cost is increased.

An object of the invention is to provide a plasma processing apparatus or an operating method of a plasma processing apparatus which accurately detects a waveform of a high frequency power supplied to a sample stage or electrodes inside the sample stage and improves a yield and an operation efficiency.

### Solution to Problem

The above object is achieved by a plasma processing apparatus and an operating method thereof. The plasma processing apparatus processes a wafer to be processed placed on an upper surface of a sample stage disposed in a processing chamber disposed inside a vacuum container by using plasma formed in the processing chamber, and includes: a high frequency power supply that forms a high frequency power supplied in a pulsed shape to the plasma or the wafer at a predetermined period during processing of the wafer; a determining device that calculates a waveform of a voltage or a current from a value of the voltage or the current of the high frequency power detected at an interval longer than the period and determines whether the waveform is within a predetermined allowable range; and a notification device that notifies a user of a determination result of the determining device and a shape of the waveform.

### Advantageous Effect

The invention can provide a plasma processing apparatus or an operating method of a plasma processing apparatus which ensures an operation of a pulse control device by monitoring a waveform of the pulse control device provided in the plasma processing apparatus and improves an operation efficiency by avoiding a maintenance work.

### BRIEF DESCRIPTION OF DRAWINGS

FIG. 1 is a longitudinal sectional diagram schematically illustrating an outline of a configuration of a plasma processing apparatus according to an embodiment of the invention.

FIG. 2 is a diagram schematically illustrating an outline of a configuration of a control microcomputer of the plasma processing apparatus according to the embodiment illustrated in FIG. 1.

FIG. 3 is a block diagram illustrating outlines of configurations of the control microcomputer and an input and output board of the embodiment illustrated in FIG. 1.

FIG. 4 is a graph schematically illustrating an example of a high frequency power for forming a bias potential detected at a predetermined sampling interval in the plasma processing apparatus according to the embodiment illustrated in FIG. 1.

FIG. 5 is a graph schematically illustrating examples of a virtual waveform and a target waveform formed by using a sampled value of an output from a high frequency bias power supply of the plasma processing apparatus according to the embodiment illustrated in FIG. 4.

FIG. 6 is a graph schematically illustrating examples of the virtual waveform and the target waveform formed by using the sampled value of the output from the high frequency bias power supply of the plasma processing apparatus according to the embodiment illustrated in FIG. 4.

FIG. 7 is a graph schematically illustrating examples of the virtual waveform and the target waveform formed by using the sampled value of the output from the high frequency bias power supply of the plasma processing apparatus according to the embodiment illustrated in FIG. 4.

FIG. 8 is a graph schematically illustrating examples of the virtual waveform and the target waveform formed by using the sampled value of the output from the high frequency bias power supply of the plasma processing apparatus according to the embodiment illustrated in FIG. 4.

### DESCRIPTION OF EMBODIMENTS

Hereinafter, embodiments of the invention will be described with reference to the drawings.

### Embodiments

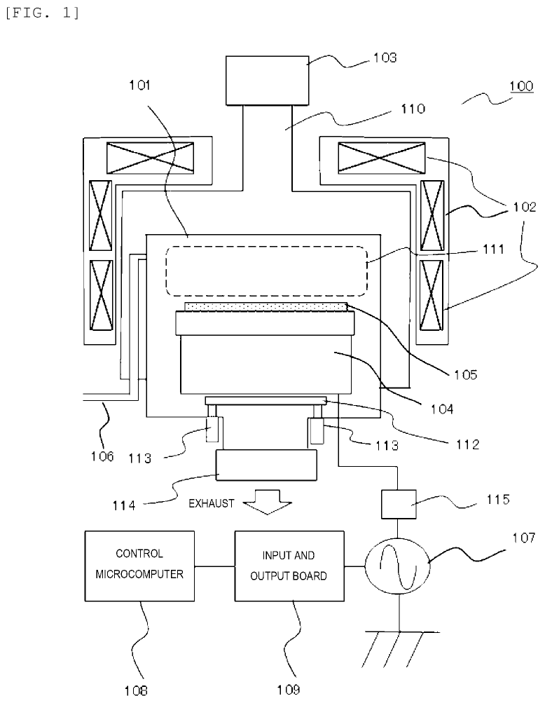

Embodiments of the invention will be described with reference to FIGS. 1 to 5. FIG. 1 is a longitudinal sectional diagram schematically illustrating an outline of a configuration of a plasma processing apparatus according to an embodiment of the invention.

A plasma processing apparatus 100 of the present embodiment includes a vacuum container unit including a vacuum container, a processing chamber that is disposed inside the vacuum container and is a space where the inside is exhausted and decompressed, and in which plasma is formed in an upper portion of the processing chamber, and a sample stage that is disposed below a region where the plasma is formed in the processing chamber and on which a semiconductor wafer that is a substrate-shaped sample to be processed is placed and held, a plasma forming unit that is disposed above or around the upper portion of the vacuum container and forms and supplies an electric field or a magnetic field for forming the plasma in the processing chamber, and an exhaust unit including an exhaust pump, such as a turbo molecular pump, which is connected to a lower side of the vacuum container and is disposed below the sample stage in the processing chamber and is disposed to be in communication with an exhaust port through which gas or the plasma inside is discharged. The plasma processing apparatus 100 is an etching processing apparatus that performs etching processing on a film on a surface of a sample disposed in the processing chamber using the plasma formed in the processing chamber.

In the figure, the plasma processing apparatus 100 includes a reaction container 101 which is the vacuum container including the processing chamber therein. A disc-shaped lid member made of a dielectric material such as quartz, which forms the reaction container 101 and covers a top surface of the processing chamber, is placed above an upper end of aside wall portion forming a cylindrical portion of an upper portion of the reaction container 101 to form a ceiling portion of the reaction container 101. A sealing member such as an O-ring is sandwiched between the lid member and the upper end of the cylindrical side wall portion of the reaction container 101, and the lid member is placed and held on the sealing member, so that a space outside the reaction container 101 and the processing chamber inside are airtightly partitioned.

Inside the reaction container 101, the processing chamber that is a space including a cylindrical portion in which plasma 111 is formed inside is disposed, and in a lower portion of the processing chamber, a sample stage 104 having a cylindrical shape is provided, on which a substrate-shaped sample 105 such as a semiconductor wafer is placed and held above an upper surface of the sample stage 104. Inside the sample stage 104, electrodes formed of a conductive material such as a metal having a disc or a cylindrical portion are disposed, and are electrically connected to a high frequency bias power supply 107 by wiring such as a coaxial cable and a cable via a matching unit 115. From the high frequency bias power supply 107, a high frequency power is supplied to the electrodes while the sample 105 is placed on the sample stage 104 and processed, and a bias potential that forms a potential difference according to a potential of the plasma 111 is formed between the sample 105 and the plasma 111 formed in the processing chamber above an upper surface of the sample 105.

Above the lid member of the upper portion of the reaction container 101, a waveguide 110 which is a pipeline for forming the plasma forming unit and supplying an electric field of a microwave for generating the plasma supplied to the processing chamber of the reaction container 101 and has a cylindrical portion extending in a vertical direction above a central portion of the lid member, is disposed. The waveguide 110 includes a square portion with a rectangular or square cross section that is a portion in which an upper end of a cylindrical portion with a circular cross section that extends in the vertical direction and one end of the square portion are connected and an axis passing through a central portion extends in a horizontal direction, and at another end portion of the square portion, an oscillator 103 such as a magnetron that is formed by oscillating the electric field of the microwave is disposed. In addition, in an outer periphery of the side wall portion having the cylindrical shape of the reaction container 101 and around the waveguide 110 above the lid member, solenoid coils 102 disposed so as to surround the outer periphery and surfaces around the waveguide 110 and generating the magnetic field supplied to form the plasma 111 in the reaction container 101 are disposed, and the plasma forming unit is formed. Although not illustrated, between a lower end of the waveguide 110 and an upper surface of the lid member, a hollow portion having a cylindrical shape whose diameter is the same as or close to that of the lid member in a visual extent and larger than that of the waveguide 110 is provided, the electric field of the microwave propagated through the waveguide 110 is diffused inside to form an electric field having a predetermined mode, and the electric field is supplied from above into the processing chamber through the lid member made of the dielectric material.

A pipeline 106 for supplying a process gas in which atoms or molecules are excited and ionized or dissociated to form the plasma 111 is connected to a side surface of the reaction container 101. A through hole in the upper portion of the reaction container 101 to which the pipeline 106 is connected is in communication with a gap between a shower plate having a disc shape which is disposed below the lid member (not illustrated) and forms a ceiling surface of the processing chamber and the lid member. The process gas flowing in the pipeline 106 is introduced into the gap between the shower plate and the lid member from a connection portion with the reaction container 101, diffuses inside the gap, and then is introduced from the above into the inside of the processing chamber through a through hole disposed in a central portion of the shower plate.

An opening communicating between the inside and the outside of the processing chamber is disposed below the sample stage 104 at a bottom of the reaction container 101, and the processing chamber and the exhaust unit are connected with the opening sandwiched therebetween. The opening having a circular shape is a place through which the gas or the plasma in the processing chamber and particles of a product generated during the processing are discharged, and constitutes the exhaust port in communication with an inlet of a turbo molecular pump 114 of the exhaust unit. In addition, the processing chamber includes a space between a lower surface of the sample stage 104 and the opening at the inside thereof, and an exhaust control valve 112 having a circular shape that moves vertically in an upper side from a position where the opening is closed in this space is disposed. The exhaust control valve 112 includes two beam-shaped flange portions that extend outward along a surface direction of a circle on an outer peripheral edge of a circular portion thereof, and is connected to a tip portion of an actuator in which a lower surface of the flange portion is attached to a bottom surface of the reaction container 101. Due to an operation of the actuator, the exhaust control valve 112 forms a valve that increases or decreases a distance between the exhaust port and the exhaust control valve 112 in the processing chamber below the sample stage 104 and increases or decreases a flow passage area of an exhaust gas from the processing chamber.

A pressure in the processing chamber is adjusted by a balance of respective amounts of supply of the process gas whose flow rate or speed is adjusted by a flow rate controller (MFC) (not illustrated) disposed on the pipeline 106 through the pipeline 106 into the processing chamber and the exhaust gas from the exhaust port due to the operation of the exhaust unit including the turbo molecular pump 114 and the exhaust control valve 112.

In addition, the high frequency bias power supply 107 of the present embodiment outputs the high frequency power to a metallic circular film-shaped or cylindrical block inside the sample stage 104 during the processing of the sample 105. A voltage or a current of the high frequency power is output with an amplitude or a magnitude thereof being changed in a period or parameters such as a frequency according to a transition of time. Such operation parameters are communicatively connected to the high frequency bias power supply 107 and an input and output board 109 via a wired or wireless communication path, and a signal indicating the operation parameters is transmitted from the input and output board 109 to the high frequency bias power supply 107, or conversely, the signal is output from the high frequency bias power supply 107 and transmitted to the input and output board 109 including a circuit that receives the signal indicating an operation state corresponding to the operation parameters.

A command signal designating the operation parameters to the input and output board 109 is transmitted from a control microcomputer 108 communicatively connected to the input and output board 109 via the wired or wireless communication path. Alternatively, the signal transmitted from the high frequency bias power supply 107 to the input and output board 109 and indicating the operation state is transmitted from the input and output board 109 to the control microcomputer 108. The high frequency bias power supply 107, the control microcomputer 108, and the input and output board 109 of the present embodiment are communicatively connected via a cable for transmitting and receiving the signal, but a wireless transmission and reception may be performed.

The command signal indicating the operation parameters calculated based on an algorithm of a software stored in a storage device by an arithmetic device in the control microcomputer 108 that receives data such as a processing condition or a recipe stored in the storage device such as RAM, ROM, or hard disk (not illustrated) in the control microcomputer 108 or information given by a user of a device is transmitted to the input and output board 109 through an interface unit inside the control microcomputer 108. In the input and output board 109, after forming the signal indicating the operation parameters based on the command signal and performing a calibration processing thereof, the signal is transmitted from the input and output board 109 to the high frequency bias power supply 107, and an operation of the high frequency bias power supply 107 is adjusted according to the signal. Conversely, during the operation of the high frequency bias power supply 107, the signal indicating the operation parameters of an output thereof is transmitted to the input and output board 109 to perform the calibration processing, and then transmitted to the control microcomputer 108 and received through the interface unit.

The high frequency bias power supply 107 of the present embodiment includes a detector that detects the operation state such as a magnitude of an output of a high frequency bias power supplied to the sample stage 104 or a change thereof at every predetermined sampling interval. An output of the detector, which is output as the operation parameters, is transmitted to the input and output board 109 and stored in the storage device inside, and after the calibration processing is performed, the signal is transmitted from the input and output board 109 to the control microcomputer 108. The high frequency bias power supply 107 may transmit the output of the detector that continuously detects the output of the high frequency power to the input and output board 109 at least during the processing of the sample 105 and detect the operation parameters from the transmitted signal at every predetermined period in the input and output board 109, and may transmit a result of the processing of calibrating the signal from the high frequency bias power supply 107 in the input and output board 109 to the control microcomputer 108 and detect the operation parameters from the transmitted signal at the every predetermined period in the control microcomputer 108.

The arithmetic device of the control microcomputer 108 detects a value of an output magnitude of the high frequency bias power supply 107 from the received signal based on the algorithm of the software in the storage device, and performs a processing of determining whether there is an abnormality described below using a predetermined reference or a reference given by the user.

Although not illustrated, the control microcomputer 108 is connected to a sensor that detects the operation states of each unit that forms the plasma processing apparatus 100 including the solenoid coil 102, the oscillator 103, and the sample stage 104 and each part provided in these units so as to be able to transmit and receive the signal by wire or wirelessly, and includes a function of calculating the command signal similarly to the high frequency bias power supply 107 based on the received signal from each of these units indicating the operating state thereof, transmitting the command signal to these units and adjusting the operation.

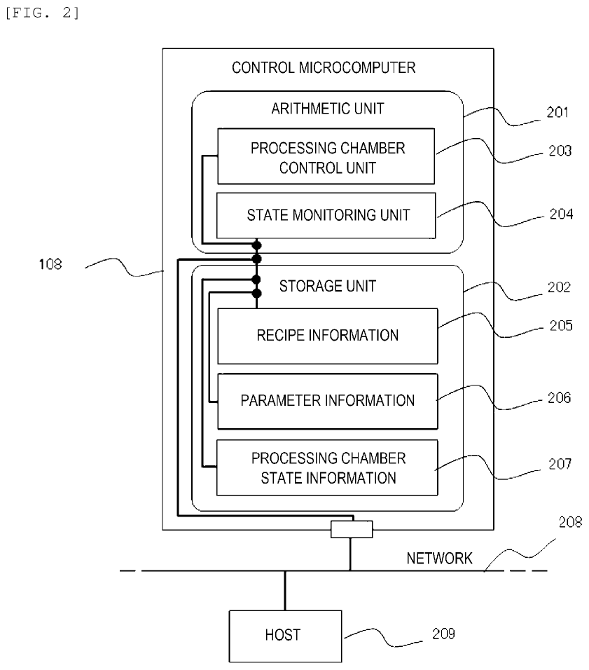

Next, a configuration of the control microcomputer 108 of FIG. 1 will be described with reference to FIG. 2. FIG. 2 is a diagram schematically illustrating an outline of the configuration of the control microcomputer of the plasma processing apparatus according to the embodiment illustrated in FIG. 1.

The control microcomputer 108 of the present embodiment includes an arithmetic unit 201 that detects an operation state of the plasma processing apparatus 100 from the signal received during the processing of the sample 105 and calculates a signal that commands an operation according to the state, and a storage unit 202 that stores the received signal or information indicating the operation state detected from the received signal. In addition, the control microcomputer 108 includes an interface unit (not illustrated), and the interface unit is communicatively connected to a host 209, which is a control device including a computer that adjusts a manufacturing operation of a building that mass-produces and manufactures a semiconductor device such as a clean room in which the plasma processing apparatus 100 is installed, via a communication facility that is schematically illustrated as a network 208. The plasma processing apparatus 100, which is one of apparatuses for manufacturing the semiconductor device in the building, or the control microcomputer 108 thereof can receive information 205 including the recipe such as a processing command of the sample 105 as needed from the host 209 via the network 208, the processing condition when processing the sample 105, or a processing order of a plurality of samples 105.

The arithmetic unit 201 of the present embodiment is a unit formed of at least one circuit or element including the arithmetic device formed of a semiconductor arithmetic circuit such as an MPU. The arithmetic unit 201 includes a processing chamber control unit 203 including the arithmetic device that calculates a command signal adjusting the operation of each unit of the plasma processing apparatus 100 based on the signal that commands the operation transmitted from the host 209 inside, and a state monitoring unit 204 including the arithmetic device that detects the operation state of each unit from the signal output from the sensor provided in each device to be adjusted and determines whether the state is within an allowable range including a reference value. The processing chamber control unit 203 and the state monitoring unit 204 may be disposed in different circuits or in the same circuit or the same device, and configured to be communicable with each other by the wiring or the cable, or may have at least a part of the processing chamber control unit 203 and the state monitoring unit 204 sharing the same circuit, element or device (for example, the arithmetic device, or the like).

In addition, the storage unit 202 includes at least one semiconductor device such as the RAM or the ROM, a storage device including a removable medium such as a hard disk drive, a CD-ROM, a DVD-ROM drive, and wiring for transmitting and receiving the signal. Each of a plurality of types of information or data such as the signal received through the interface unit provided in the control microcomputer 108, or the signal indicating the command signal or the data calculated and detected by the arithmetic unit is stored in the storage device described above. In the present embodiment, in the storage unit 202, as the information stored in the storage device, the software for performing a calculation in which the arithmetic unit 201 detects the operation state from the signal output from the sensor provided in each device of the plasma processing apparatus 100 to be adjusted, and further calculates the command signal adjusting the operation of each unit is stored in advance, and recipe information 205, parameter information 206, and processing chamber state information 207 acquired in response to the command from the arithmetic unit 201 as the information necessary for arithmetic processing are included.

The recipe information 205 is information including the processing condition of the sample 105, and is given in advance by the user before the processing is started. The recipe information 205 of the present embodiment includes information on time of any step in the processing of the sample 105 including at least one step, a pressure in the processing chamber in the step, a type of the gas supplied, and the reference value of the output of each device of the plasma processing apparatus 100 to be controlled.

The parameter information 206 includes information on parameters of an operation unique to the plasma processing apparatus 100, such as the configuration of the plasma processing apparatus 100 or an operating range of each device to be controlled, for example, the operating range of each device in an operation including the processing of the sample 105 of the plasma processing apparatus 100 such as an upper limit value or a lower limit value of an output performance of the high frequency bias power supply 107. In particular, the information that is given in advance by the user or manufacturer and does not vary regardless of the processing condition of the sample 105 is included.

The processing chamber state information 207 includes information such as a signal indicating a state of the device transmitted from each device to be controlled to the control microcomputer 108, or a signal output from a detector such as a sensor indicating a state of the surface of the sample 105 which changes as the processing of the sample 105 progresses or a state of the plasma 111 inside the processing chamber. Information that changes according to the processing condition for each step transferred in the processing of the sample 105 or the progress of the processing during an optional step is included.

The operation of the arithmetic unit 201 is as follows.

According to the algorithm of the software stored in advance in the storage unit 202, the processing chamber control unit 203 reads the recipe information 205, the parameter information 206, and the processing chamber state information 207 stored in the storage device and calculates the command signal of the operation of each device and the command signal for performing the operation. In addition, the signal output from the device to be controlled or the detector received by the control microcomputer 108 via a communication unit is calculated or detected in the state monitoring unit 204 as the information indicating these states according to the algorithm of the software, is transmitted as the data to the storage unit 202 according to the command from the arithmetic device, and is stored in the processing chamber state information 207.

Further, in the state monitoring unit 204, at least one of the data of the recipe information 205, the parameter information 206, and the processing chamber state information 207, which are detected from the signal transmitted from each device to be controlled or the sensor during the processing of the sample 105 and are stored in the storage unit 202, is read out at every predetermined time interval, and based on the data, it is determined whether the operation state of each device to be controlled is within the allowable range, or whether an abnormal state occurs. Further, when it is determined that the abnormal state occurs, the information indicating that there is the abnormal state or that the abnormal state occurs is transmitted to the host 209 via the network 208 and is transmitted to the processing chamber control unit 203. Alternatively, the command signal is transmitted to the processing chamber control unit 203 so as to perform an operation or a processing when the abnormality occurs.

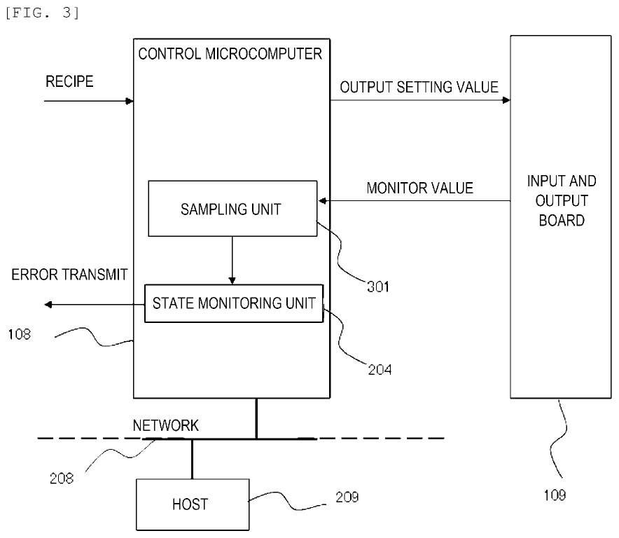

Next, operations of the control microcomputer 108 and the input and output board 109 will be described with reference to FIG. 3. FIG. 3 is a block diagram illustrating outlines of configurations of the control microcomputer and the input and output board of the embodiment illustrated in FIG. 1.

When adjusting the operation of the plasma processing apparatus 100, according to the data of at least one of the recipe information 205, the parameter information 206, and the processing chamber state information 207 stored in the storage unit 202 illustrated in FIG. 2, or the recipe data given from the host 209 via the network 208 which is the processing condition such as the film to be processed of the sample 105 or a supply amount of the process gas, the pressure of the processing chamber, the control microcomputer 108 calculates the command signal that adjusts the operation of a target device in the processing chamber control unit 203, and transmits the signal to the input and output board 109.

The state monitoring unit 204 in the control microcomputer 108 receives the signal indicating the processing condition (the recipe) of the sample 105 transmitted from the host 209, which is received by the interface unit of the control microcomputer 108 via the network 208, and detects, from the signal, the data of the processing condition such as the information on the reference value of the output of each device of the plasma processing apparatus 100 during the processing and store the data in the storage unit as the recipe information 205. Further, a value (a monitor value) indicating the operation or a processing state of each device of the plasma processing apparatus 100 is detected from the signal from each device to be controlled or the detector of the plasma processing apparatus 100 received through the input and output board 109, and is stored in the storage unit 202 as the processing chamber state information 207. Then, when it is determined whether the monitor value stored as the processing chamber state information 207 is within the allowable range, or whether the abnormality occurs, and it is determined that the value is outside the allowable range, the information indicating an occurrence of the abnormality and a content of the abnormal state is transmitted to the host 209 via the network 208.

The state monitoring unit 204 reads the monitor value included in the processing chamber state information 207 during the processing of the sample 105 at a predetermined time interval P1 and determines the occurrence of the abnormality. Therefore, the control microcomputer 108 includes a sampling unit 301 that receives the signal from each device to be controlled or the detector of the plasma processing apparatus 100 at a predetermined time interval P0 that is equal to or sufficiently smaller than the time interval P1 via the input and output board 109. The sampling unit 301 may transmit the command signal to the input and output board 109 so as to transmit the signal calibrated by receiving the signal from each device to be controlled or the detector of the plasma processing apparatus 100 at the predetermined time interval P0. Alternatively, the sampling unit 301 may transmit the command to the input and output board 109 so as to transmit a result of calibration processing of the signal from each device to be controlled or the detector that is transmitted continuously or at an interval sufficiently smaller than the predetermined time interval P0 to the sampling unit 301, and transmit the received signal from the sampling unit 301 to the state monitoring unit 204, and may store the data of the signal indicating the monitor value for each time interval P0 obtained from the signal of the sampling unit 301 by the state monitoring unit 204 in the storage unit 202 as the processing chamber state information 207.

In particular, in the present embodiment, the state monitoring unit 204 has a function of detecting the magnitude of the high frequency power output from the high frequency bias power supply 107 at the predetermined time interval (hereinafter, the sampling interval), calculating the waveform as a target to determine whether there is the abnormality for the high frequency power output from the high frequency bias power supply 107 from the result, and comparing the waveform to be determined with a reference waveform to determine whether there is the abnormality. A waveform created in the present embodiment will be described with reference to FIG. 4. FIG. 4 is a graph schematically illustrating an example of the high frequency power for forming the bias potential detected at the predetermined sampling interval in the plasma processing apparatus according to the embodiment illustrated in FIG. 1.

The high frequency bias power supply 107 of the present embodiment outputs the high frequency power by changing the magnitude of the amplitude of the voltage or the current of the high frequency power in each period and order predetermined by at least two different values with respect to the electrodes inside the sample stage 104 output during the processing of the sample 105 via the matching unit 115 and repeating the magnitude periodically. FIG. 4 shows an example in which the amplitude of the voltage of the high frequency power is alternately output for different periods predetermined by each of predetermined values X and 0, which is repeated at a predetermined period.

When such an output is generated from the high frequency bias power supply 107, the command signal indicating a timing of the output transmitted from the input and output board 109 that receives the command from the control microcomputer 108 to the high frequency bias power supply 107 is intermittent in a pulsed shape with a period in which the amplitude is constant as X and a period in which the amplitude is 0 when a horizontal axis represents time and vertical axis represents output. However, the waveform of the voltage of the power actually output from the high frequency bias power supply 107 does not have a perfect step shape, and “blurring” occurs since a rate of a change is finite between an increase of the output of the high frequency bias power supply 107 at a rise and a decrease of the output at an end.

In the example, as illustrated as an actual waveform 401 in FIG. 4, the output changes every period T between a state where an output value is 0, that is, the amplitude is 0 and a time at which a voltage value starts increasing at a time corresponding to a start of a pulse-shaped output of the amplitude X in the command signal, reaches a maximum value (a peak value), then starts decreasing, and the output value becomes 0 again. In addition, the output changes in a curve in which a ratio of the voltage value changes greatly in an initial stage and gradually becomes gentle only during a predetermined period from the start and end times of the period corresponding to the period of each pulse-shaped output of the command signal.

In the present embodiment, such high frequency power is supplied to the electrodes inside the sample stage 104, and the signal resulting from a detection by a voltage sensor (not illustrated) disposed inside the high frequency bias power supply 107 not indicating the voltage value of the power or on a power feeding path formed of the wiring such as the coaxial cable electrically connecting the high frequency bias power supply 107 and the matching unit 115 is transmitted to the input and output board 109. The voltage sensor may be disposed on the power feeding path between the matching unit 115 and the electrodes. The signal indicating the voltage value calibrated on the input and output board 109 is transmitted to the sampling unit 301 inside the control microcomputer 108, and further the sampling unit 301 transmits to the state monitoring unit 204 the received signal indicating the voltage value from the input and output board 109 for each predetermined sampling period T.

When the period T of the voltage of the high frequency power changing as in the example and a sampling period T do not match, sampling values 402, which are values of a plurality of voltages for each period T detected by the state monitoring unit 204, are not constant values and different values even when the voltages of the high frequency power output in the pulsed shape at the period T are voltages in which the waveforms (hereinafter, pulse waveforms) indicating the magnitude of the values are the same for each period T. In addition, a value of a ratio (hereinafter, referred to as a phase) of a detected time of each sampling value 402 or a time (hereinafter, referred to as a sampling time) on time series corresponding to each sampling period T in the sampling unit 301 which can be considered to be detected to a time from a starting position (for example, a position where the amplitude of the pulse waveform is 0 or a corresponding time) that is a reference of one pulse waveform of each actual waveform 401 including the sampling time or the period τ of the time varies with each sampling time.

In the present embodiment, the period T of a detection of the value in the sampling unit 301 and the state monitoring unit 204 is determined appropriately, a plurality of values detected from signals indicating a voltage at the sampling time in each period T and each sampling value 402 in which a phase value in the period τ varies are used to create a waveform for one period by the sampling value 402. Such a waveform is compared with a target waveform serving as a reference for determination to determine whether there is the abnormality in the supply of the high frequency power, and an operation efficiency of the plasma processing apparatus 100 and a processing yield are improved.

In the sampling unit 301, the sampling values 402 are detected from the signals indicating the monitor values of the voltages transmitted from the input and output board 109 at every constant period T having a value larger than the period τ of the pulse waveform, and the phase of each sampling value 402 in one period τ of the pulse waveform is calculated.

Further, the state monitoring unit 204 has a function of receiving data indicating the sampling values 402 and phase values thereof stored in the storage device inside the sampling unit 301 at the predetermined interval, calculating the waveform to be determined from the data of these sampling values 402, calculating the value at each sampling time of the waveform as the reference obtained based on a predetermined formula, and determining whether there is the abnormality in the pulse waveform obtained by comparing the data of these two waveforms.

Further, the state monitoring unit 204 stores the data of the waveform calculated by the user and each sampling value 402 in the storage unit 202 inside, or transmits the data to the storage device such as the RAM, the ROM or a hard disk device communicatively connected to the control microcomputer 108 at another location for storage. Further, it may be configured to transmit the data to a display such as a CRT or a liquid crystal monitor (not illustrated) provided in the plasma processing apparatus 100 and display the data on the display.

In the present embodiment, in calculating the pulse waveform of the high frequency power and determining whether there is the abnormality, it is necessary that the waveform created using the sampling value 402 obtained from the monitor value of the pulse waveform of the high frequency power reproduces the actual waveform 401 more accurately, and further it is desirable that there are many sampling values 402 of different phases of the one period τ of the pulse waveform. Conditions for increasing the reproducibility of the actual waveform 401 with such sampling values 402 will be described.

How the phases of the plurality of sampling values 402 detected at each sampling time sequentially from the signal indicating the monitor value vary will be examined. An amount of the changing in the phase for each sampling value 402 is obtained from an absolute value of a value obtained by subtracting a remainder from ½ of the period τ of the pulse waveform, and the remainder is obtained by dividing the sampling period T by the period T of the pulse waveform. For example, when the sampling period T is 100 ms and the period τ of the pulse waveform is 70 ms, a phase variation corresponding to 30 ms with respect to the period τ of the pulse waveform occurs at each sampling time. In this case, when the phase of an initial sampling value 402 in the plurality of sampling values 402 is 0, that is, the amplitude of any one pulse waveform is 0 and a time when starting an increase reaches, the phase in the period τ of each pulse waveform varies by 30 ms (or the ratio to the period τ) in order, such as 30 ms, 60 ms, 20 ms, 50 ms . . . at each sampling time after a starting time.

In the example, assuming that the plurality of sampling values 402 used for creating the pulse waveform are obtained in the time series at the plurality of sampling times between the starting time when the phase is 0 and a last time, when the period τ is divisible by the amount of the phase variation, that is, a value of a quotient obtained by dividing a least common multiple of the sampling period T and the period τ of the pulse waveform by the sampling period T becomes the sampling value 402 in which one is a value other than 0. As an example, when the sampling period is 90 ms and the monitoring target period is 60 ms, a variation value for each sampling is 30 ms. In this case, the time series to be followed when creating one period of the pulse waveform is only two of 30 ms and 60 ms, so that the reproducibility of the actual waveform is significantly reduced.

In addition, even when the phase variation that occurs at each sampling time is large, the number of the sampling values 402 acquired by the sampling unit 301 during any period may be insufficient to create the pulse waveform for one period. In order to solve the above problems, it is necessary to determine the allowable range of the amount of the phase variation that can be used to create the pulse waveform from the plurality of acquired sampling values 402 and select the sampling period T or the period τ of the pulse waveform such that the phase is within the allowable range. In the present embodiment, a minimum value of the amount of the phase variation is predetermined, and the sampling period T at which the phase is equal to or greater than the minimum value is determined.

That is, in the present embodiment, the value of the quotient obtained by dividing the period τ of the pulse waveform of the high frequency power by a minimum number of the sampling values 402 required to create the pulse waveform with a desired accuracy is predetermined as the minimum value of the phase. When determining the abnormality in the waveform of the high frequency power from a calculated value of the pulse waveform created from the data obtained by sampling the monitor value of the output of the high frequency power that varies in the pulsed shape at the predetermined period τ in the period T, the number of the sampling values 402 used to create the sampling period T or the pulse waveform is selected such that the variation value of the phase in the period τ of the pulse waveform is equal to or greater than the above minimum value and the period τ is not a natural multiple of the variation value of the phase. By satisfying such a condition, it is possible to determine whether there is the abnormality without being affected by the magnitude of values of the sampling period T of the monitor value acquired by the sampling unit 301 and a Nyquist period of the pulse waveform to be sampled.

Next, details of an operation of the sampling unit 301 will be described. The sampling unit 301 receives the signal indicating the monitor value of the pulse waveform from the input and output board 109 in the predetermined period during the processing of the sample 105 for the predetermined sampling period T, or stores the value of the signal indicating the monitor value received from the input and output board 109 for each period T as array (or list) data. Of the data, the data at a Jth sampling time from the starting time is stored as a Jth element as an element in a Jth order, and subsequent data is also sequentially stored in (J+1)th element, or the like.

Further, the position (the phase) in the one period τ of the pulse waveform at the sampling time corresponding to the element of each stored data and the number thereof is calculated. For example, a remainder obtained by dividing a result of multiplying an element number J by the sampling period T by the period τ of the pulse waveform given as the information from the user to the control microcomputer 108 indicates the phase in the one period τ of the pulse waveform at the sampling time corresponding to the Jth element of the Jth data stored in the array (or the list). The phase of each element of the array in which these sampling values 402 are stored is associated with each element and stored in the sampling unit 301, for example, the array in which the sampling values 402 of the monitor values are stored may include the sampling values 402 and the phase values in the period τ of the sampling time associated with the sampling values 402 and the sampling time described above as the elements.

Next, an operation of the state monitoring unit 204 will be described. The sampling unit 301 receives the signal indicating each element including the data of the sampling value 402 for the predetermined period of time, for example, one second in the present embodiment of the data stored in the array or the list as each element and newly stores the signal as the array data in the storage unit 202, and then rearranges the data of the array by performing sorting in an order of the phase in the one period T of the pulse waveform corresponding to the data of each element. At this time, the data stored in each element of the array in the storage unit 202 may be rewritten and stored again, or may be stored in the storage unit 202 as another array.

In order to perform a comparison with the value of the target waveform that serves as the reference, which will be described later, the time (offset) between the sampling time when the sampling for creating the waveform for determination and a rising timing of the pulse waveform indicated by the monitor value is determined. Of array elements sorted in the order of the phase in the one period τ in the state monitoring unit 204, an element value of any element number K of the array, that is, the sampling value 402 as a Kth element is selected to be smaller than that of a next (K+1)th element, and further, an Nth element having a smallest value is selected from the elements. An element number N corresponding to the Nth element is considered to be the element number where the amplitude of the pulse waveform to be created for determination starts to increase, and the phase of the Nth element is considered to be an offset position or an offset phase in the one period τ of the pulse waveform.

Using the offset determined in this way, the phase of each element of the array from the Nth element to M−1 elements which is the predetermined number ((N+M)th element) including the period of the one period τ of the pulse waveform is recalculated. When a result of subtracting the offset phase from the phase of each element is 0 or a positive number, the subtracted result is set as the phase in the period of one pulse waveform of each element. When the result of the subtraction is negative, the value obtained by adding the period τ of the pulse waveform to the result of the subtraction is determined as a position or a phase in the period of one pulse waveform of the Nth element of each element. The phase value thus determined again or a time value corresponding to the phase in the pulse waveform for the one period τ is rewritten as the data of each element of the array or stored as the data of the other array together with other data of each element of an original array. Using the phase and the time recalculated in this way, an array of the elements in which the elements from the Nth element to the (N+M)th element in which the monitor values including those for one period of the above waveform are stored are arranged in the order of the phase from the offset is called a virtual waveform array.

Next, in order to obtain the reference value used when determining whether there is the abnormality in the values stored in the elements of the virtual waveform array created above in the state monitoring unit 204, a theoretical value of the sampling value 402 at the sampling time or the phase of each element of the virtual waveform array is calculated from a formula of the target waveform that represents a time change of the voltage or the current of the output high frequency power by using a time constant of the oscillator that oscillates and forms the pulse waveform of the high frequency power included in the high frequency bias power supply 107 and output from the high frequency bias power supply 107. The parameters used in the formula of the target waveform for calculating the theoretical value of the monitor value such as the time constant of the oscillator of the example are input in advance by the user or a designer of the device and stored in the control microcomputer 108.

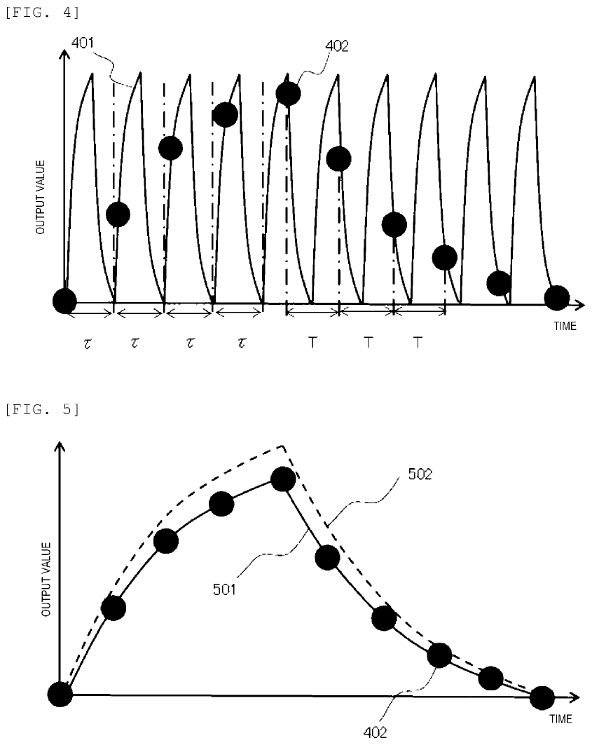

In this way, a creation of the elements of the array showing a virtual waveform using the sampling values 402 of the monitor values and a creation of the target waveform showing the theoretical value of the monitor values will be described with reference to FIG. 5. FIG. 5 is a graph schematically illustrating examples of the virtual waveform and the target waveform formed by using the sampled value of the output from the high frequency bias power supply of the plasma processing apparatus according to the embodiment illustrated in FIG. 4. The target waveform of the example is created by the arithmetic device disposed inside the control microcomputer 108 from the software stored in the storage unit of the control microcomputer 108 based on the condition of a virtual waveform 501 given in advance by the user of the plasma processing apparatus 100 or the signal from the host 209 or the time constant when controlling the device to be controlled of the control microcomputer 108 of the plasma processing apparatus 100.

In this figure, the sampling values 402 of elements of the virtual waveform array for one period of the pulse waveform are illustrated as black dots, and a graph connecting the black dots of the plurality of elements with a solid line is called the virtual waveform 501. In addition, a graph in which the target waveform in each phase of one period of the pulse waveform from the Nth element to the (N+M)th element is illustrated by a broken line is called a target waveform 502.

Shapes of the virtual waveform 501 and the target waveform 502 are required to have a difference between values at times within a predetermined allowable range. For example, when a value of each phase of the virtual waveform 501 causes an overshoot or an undershoot with respect to a value of the target waveform 502, it is necessary to perform a detection. In the present embodiment, the magnitude of a variation of the virtual waveform 501 from the target waveform 502 is detected using a correlation coefficient calculated from the value of the virtual waveform 501 and the value of the target waveform 502.

As the value of the target waveform 502 at each time, information of a duty (Duty) ratio and a period value of the pulse waveform input by the user or the designer of the plasma processing apparatus 100 and stored in the control microcomputer 108 is used. For example, when the time from the starting time of the phase 0 in one period of the target waveform 502 is less than a product value of a duty (Duty) ratio value and the period value, since the time is in a rising period when the amplitude of the pulse waveform is increased, as an expression expressing the pulse waveform during this rising period with an output setting value of the pulse waveform being X, a time from the starting time of any time during the rising period being S1, and the time constant of the oscillator being T0, the following Expression (1)

$$\begin{matrix}[ Expression 1 ] & \\ X \times ( 1 - e ( - \frac{S 1}{T 0} ) ) & ( 1 )\end{matrix}$$

is used to obtain the time value of the target waveform by the arithmetic device inside the control microcomputer 108.

In addition, when the time from the starting time of the phase 0 is equal to or greater than the product value of the duty (Duty) ratio value and the period value, since the time is in a falling period when the amplitude of the pulse waveform is decreased, as an expression expressing the pulse waveform during this falling period with a result of subtracting the product value of the period and the duty (Duty) ratio from any time during the falling period being S2, the following

### Expression (2)

$$\begin{matrix}[ Expression 2 ] & \\ X \times e ( - \frac{S 2}{T 0} ) & ( 2 )\end{matrix}$$

is used to obtain the time value of the target waveform by the arithmetic device inside the control microcomputer 108.

The calculated value of the target waveform at the same time as each element of the virtual waveform array or the phase in the period τ, which is calculated by the arithmetic device of the state monitoring unit 204 based on such a target waveform expression, is stored in the storage unit 202 together with the time and phase values as the array elements according to the command signal from the arithmetic device. Such an array is called a target waveform array.

The state monitoring unit 204 uses the virtual waveform array and the target waveform array to determine whether there is the abnormality in a pulse waveform shape at every predetermined time interval. The determination is that a difference between a maximum value of the sampling values 402 stored as the elements of the virtual waveform array and a maximum value of target waveform values stored in the target waveform array is within the allowable range, and is performed by determining whether conditions are satisfied, the conditions including that the maximum value of the sampling values 402 stored in the virtual waveform array does not exceed the maximum value of the target waveform values of the target waveform array, the difference between the sampling value 402 and the target waveform value having the same element number (that is, the phase at the same time or the period τ of the virtual waveform array and the target waveform array is within a predetermined allowable range, and the correlation coefficient between the virtual waveform array and the target waveform array is equal to or greater than a predetermined reference value.

Of the above conditions, a first condition is to determine whether the magnitude of the high frequency power output from the high frequency bias power supply 107 to the electrodes inside the sample stage 104 in the plasma processing apparatus 100 is within the predetermined allowable range suitable for processing the sample 105, and whether the plasma processing apparatus 100 is overloaded. A second condition is to determine whether the pulse waveform of the current or the voltage of the high frequency power output from the high frequency bias power supply 107 is within the predetermined allowable range including a desired range suitable for processing the sample 105. A third condition is to determine whether the pulse waveform causes the undershoot or the overshoot with respect to the target waveform.

In the present embodiment, a procedure that calculates the correlation coefficient under the third condition will be described. In the plasma processing apparatus 100 of the example, when calculating the correlation coefficient in the arithmetic unit 201, a covariance of the virtual waveform array and the target waveform array and a standard deviation of each array are calculated.

The covariance is calculated by first subtracting an average value of the sampling values 402 of each element from the sampling value 402 of the element of any number in the virtual waveform array to calculate a deviation of the sampling value 402 of the element of the number. Similarly, the deviation of the target waveform value of the element of any number in the target waveform array is calculated in the same manner. Further, a value obtained by calculating a product of deviations calculated for the elements of each number of the virtual waveform array and the target waveform array, adding the product value of the deviations calculated above for all the N+M elements including the one period T of the pulse waveforms of the two arrays, and dividing a total sum by the number of the elements N+M is calculated as the covariance of these waveform arrays.

Next, the standard deviation of each of the two waveform arrays is calculated. With respect to the virtual waveform array, the deviation of the sampling value 402 of the element of any number in the virtual waveform array is calculated in a similar manner as above. The value of the deviation calculated when calculating the covariance may be used. A value obtained by calculating a square root of the total sum obtained by adding squared values of the deviations of each element for all the N+M elements including the one period T of the pulse waveform and dividing a square root value by the number of the elements N+M is calculated as the standard deviation of the virtual waveform array. Similarly, the standard deviation of the target waveform array is calculated.

The correlation coefficient is calculated using the covariance of the virtual waveform array and the target waveform array obtained in this way and the standard deviation of each waveform array. The correlation coefficient is calculated by the arithmetic device of the state monitoring unit 204 of the arithmetic unit 201 by dividing the covariance of the virtual waveform array and the target waveform array by the product of the standard deviations of each waveform array.

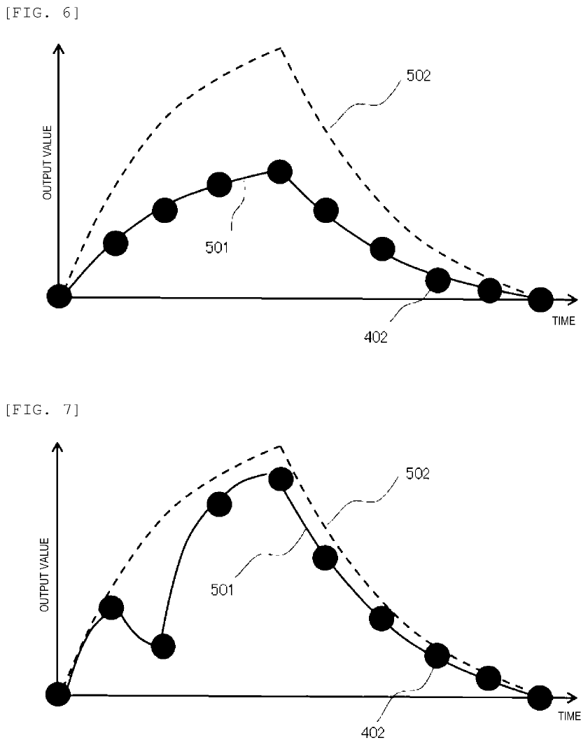

Next, a procedure that determines whether there is the abnormality in the pulse waveform shape at the predetermined time interval using the virtual waveform array and the target waveform array according to the present embodiment will be described with reference to FIGS. 6 to 8. FIGS. 6 to 8 are graphs schematically illustrating examples of the virtual waveform and the target waveform formed by using the sampled value of the output from the high frequency bias power supply of the plasma processing apparatus according to the embodiment illustrated in FIG. 4. In these figures, the same parts as those in the first embodiment illustrated in FIGS. 1 to 5 are designated by the same reference numerals, and detailed description thereof will be omitted.

In the embodiment, states of the virtual waveform 501 and the target waveform 502 when it should be determined that the abnormality occurs in the virtual waveform are divided into three types of patterns, it is determined whether there is any of the patterns, and it is determined whether there is the abnormality in the virtual waveform 501. That is, the patterns are classified in a case where the value of the virtual waveform 501 is always insufficient with respect to the target waveform 502, a case where the difference between the value of the virtual waveform 501 and the value of the target waveform 502 near a specific time or a specific phase during the one period τ of the pulse waveform is continuously large, and a case where the virtual waveform 501 and the target waveform 502 are significantly different.

For each abnormal pattern, a detection of a difference value between maximum values of the values of the respective elements of the virtual waveform array showing the virtual waveform 501 and the target waveform array showing the target waveform 502 described in FIG. 5 and a comparison with an allowable value are set as monitoring 1, a detection of the difference value of the values of the elements of the virtual waveform array and the target waveform array at any time or phase and a comparison with the allowable value are set as monitoring 2, and further a detection of the correlation coefficient of the virtual waveform array and the target waveform array and a comparison with the reference value thereof are set as monitoring 3.

Further, in the present embodiment, for determining whether there is the abnormality, for the monitoring 1, when a range of the allowable value is greater than these values in which the difference between the detected maximum values is less than ±15% of the predetermined value, it is determined that there is the abnormality. Further, for the monitoring 2, when the value of the sampling value 402 of each element of the virtual waveform array is equal to or greater than ±10% of the target waveform value of the element of the target waveform array at the same time or phase as the virtual waveform array, it is determined that there is the abnormality. Further, for the monitoring 3, when a value of the correlation coefficient is 0.7 or less, it is determined that there is the abnormality.

A first pattern will be described with reference to FIG. 6. FIG. 6 is a graph schematically illustrating an example in which the value of the sampling value 402 indicating the virtual waveform 501 stored in the virtual waveform array is smaller than that of the target waveform 502 indicated by the solid line as a whole. A condition that there is the abnormality in which the output of the virtual waveform 501 in this figure is insufficient is a case where it is determined that the monitoring 1 is abnormal, the monitoring 2 is abnormal at all times or phases, and the monitoring 3 is normal (no abnormality). When it is determined by the arithmetic device of the state monitoring unit 204 that the above condition is satisfied, the control microcomputer 108 transmits a command for stopping the processing of the sample 105 or correcting the output and operation thereof to each device to be controlled of the plasma processing apparatus 100 including the high frequency bias power supply 107. In the output correction, in the control microcomputer 108, an output shortage radio of the virtual waveform 501 to the target waveform 502 for each time is calculated, and a setting of an output value, which is obtained by adding a product of an output shortage ratio obtained for the input and output board 109 and a setting value of the output correcting the output shortage radio, is transmitted.

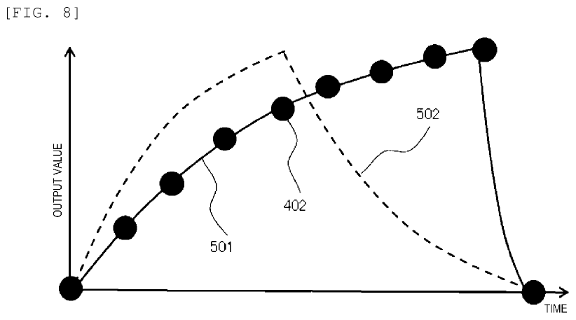

A second pattern will be described with reference to FIG. 7. FIG. 7 is a graph schematically illustrating an example in which the virtual waveform 501 created from the sampling value 402 differs significantly from the target waveform 502 only at the specific time or phase. The condition for determining that the difference between the values of the virtual waveform 501 and the target waveform 502 at the specific time or phase is continuously large is a case where the abnormality is continuously detected only for the predetermined time or phase in the monitoring 2 from the specific time, while the monitoring 1 and the monitoring 3 are determined to have no abnormality. When the above condition is satisfied, the abnormality in the device to be controlled or an accompanying environment is assumed, so that the control microcomputer 108 does not transmit the command for the output correction, but transmits the command for stopping the processing of the sample 105 of the plasma processing apparatus 100.

A third pattern will be described with reference to FIG. 8. FIG. 8 is a graph schematically illustrating an example in which the virtual waveform 501 created from the sampling value 402 differs significantly from the target waveform 502 in a waveform shape. The condition that the virtual waveform 501 and the target waveform 502 are significantly different is a case where the monitoring 3 is determined to be abnormal regardless of states of the monitoring 1 and the monitoring 2. When the above condition is satisfied, the abnormality in the device to be controlled or the accompanying environment is assumed, so that the control microcomputer 108 does not issue the command for correcting the output, but transmits the command for stopping the processing of the sample 105.

According to the above embodiment, the abnormality in the waveform of the high frequency power output from the high frequency bias power supply 107 can be detected with high accuracy, and the processing yield of the sample 105 is improved.

### REFERENCE SIGN LIST

101 reaction container
102 solenoid coil
103 oscillator
104 sample stage
105 sample
106 pipeline
107 high frequency bias power supply
108 control microcomputer
109 input and output board
201 arithmetic unit
202 storage unit
203 processing chamber control unit
204 state monitoring unit
205 recipe information
206 parameter information
207 processing chamber state information
208 network
209 host
301 sampling unit
401 actual waveform
402 sampling value
501 virtual waveform
502 target waveform

1. A plasma processing apparatus that processes a wafer to be processed placed on an upper surface of a sample stage disposed in a processing chamber that is disposed inside a vacuum container by using plasma formed in the processing chamber, the plasma processing apparatus comprising:
a high frequency power supply configured to form a high frequency power supplied in a pulsed shape to the plasma or the wafer at a predetermined period during processing of the wafer; a determining device configured to calculate a waveform of a voltage or a current from a value of the voltage or the current of the high frequency power detected at an interval longer than the period and determine whether the waveform is within a predetermined allowable range; and a notification device configured to notify a user of a determination result of the determining device and a shape of the waveform.

2. The plasma processing apparatus according to claim 1, wherein
the high frequency power supply that outputs the high frequency power for forming a bias potential on the wafer is electrically connected to electrodes disposed inside the sample stage.

3. The plasma processing apparatus according to claim 1, wherein
the determining device is configured to determine whether a magnitude of an amplitude of the calculated waveform and a result of a comparison between the calculated waveform and a reference waveform are within the predetermined allowable range.

4. The plasma processing apparatus according to claim 3, wherein
the determining device is configured to compare the calculated waveform with the reference waveform and determine whether at least one of a value of a difference between the calculated waveform and the reference waveform and a correlation between the calculated waveform and the reference waveform is within the allowable range.

5. The plasma processing apparatus according to claim 3, wherein
the determining device includes a storage device that stores information indicating the reference waveform in advance before the processing of the wafer is started, and is configured to compare the reference waveform calculated from the stored information with the calculated waveform.

6. An operating method of a plasma processing apparatus that processes a wafer to be processed mounted on an upper surface of a sample stage disposed in a processing chamber disposed inside a vacuum container by using plasma formed in the processing chamber,
the plasma processing apparatus including: a high frequency power supply configured to form a high frequency power supplied in a pulsed shape to the plasma or the wafer at a predetermined period during processing of the wafer,
the operating method comprising: calculating a waveform of a voltage or a current from a value of the voltage or the current of the high frequency power detected at an interval longer than the period determining whether and the waveform is within a predetermined allowable range; and modifying an operating condition that processes the wafer when the waveform is determined to be outside the allowable range.

7. The operating method of a plasma processing apparatus according to claim 6, further comprising:
stopping the processing of the wafer when the waveform is determined to be outside the allowable range.

8. The operating method of a plasma processing apparatus according to claim 6, wherein
the high frequency power supply that outputs the high frequency power for forming a bias potential on the wafer is electrically connected to electrodes disposed inside the sample stage.

9. The operating method of a plasma processing apparatus according to claim 6, further comprising:
determining whether a magnitude of an amplitude of the calculated waveform and a result of a comparison between the calculated waveform and a reference waveform are within the predetermined allowable range.

10. The operating method of a plasma processing apparatus according to claim 9, further comprising:
comparing the calculated waveform with the reference waveform and determining whether at least one of a value of a difference between the calculated waveform and the reference waveform and a correlation between the calculated waveform and the reference waveform is within the allowable range.

11. The operating method of a plasma processing apparatus according to claim 6, further comprising:
determining whether a magnitude of an amplitude of the calculated waveform and a result of a comparison between the calculated waveform and a reference waveform are within the predetermined allowable range; and correcting an output setting value of the voltage or the current of the high frequency power in previous wafer processing by using the magnitude of the amplitude of the calculated waveform and the result of the comparison between the calculated waveform and the reference waveform when the waveform is determined to be outside the allowable range.
